(19) United States
(12) Patent Application Publication
(10) Pub. No.: US 2008/0299374 A1
(43) Pub. Date: Dec. 4, 2008

(54) TRANSPARENT ELECTRODE COMPRISING CARBON NANOTUBE AND METHOD OF PREPARING THE SAME

(75) Inventors: Jae-young CHOI, Suwon-si (KR); Seong-jae CHOI, Yongin-si (KR); Hyeon-jin SHIN, Yongin-si (KR); Seon-mi YOON, Yongin-si (KR); Ki-kang KIM, Seoul (KR); Young-hee LEE, Seoul (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/045,216

(22) Filed: Mar. 10, 2008

(30) Foreign Application Priority Data
Mar. 9, 2007 (KR) 10-2007-0023590

(51) Int. Cl. B01J 19/10; D01F 9/12; B32B 9/00; B06B 1/20; B05D 5/12

(52) U.S. Cl. 428/220; 423/447.1; 204/157.42; 427/601; 427/77; 977/746

(57) ABSTRACT

Disclosed is a method of manufacturing a transparent electrode having a carbon nanotube. The carbon nanotube powder is dispersed in a solvent to form a carbon nanotube ink. The carbon nanotube ink is coated on a substrate to prepare a carbon nanotube film. The carbon nanotube has a defect formed on a surface thereof. The defect is formed through an acid treatment process of immersing the carbon nanotube powder or the carbon nanotube film in a nitric acid, a sulfuric acid, a hydrochloric acid, a phosphoric acid, or a mixture thereof. The defect can be formed through an ultrasonic treatment process of exposing the carbon nanotube powder or the carbon nanotube film to an ultrasonic wave having a predetermined frequency and intensity.

This application claims priority to Korean Patent Application No. 10-2007-0023590 filed on Mar. 9, 2007, and all the benefits accruing therefrom under 35 U.S.C. §119, the contents of which in its entirety are hereby incorporated by reference.

### BACKGROUND OF THE INVENTION

This disclosure relates to a transparent electrode that comprises carbon nanotubes and to methods of preparing the same.

In general, devices such as display devices or solar cells include transparent electrodes because they form images or produce electric powder by transmitting light. Transparent electrodes are generally formed of indium tin oxide (ITO) and have a wide range of applications. However, as the cost of ITO is increasing with the increased consumption thereof, use of ITO is becoming uneconomical. In particular, when a transparent electrode formed of ITO is bent, cracks occur therein, which leads to an increase in the electrical resistance thereof. Thus, this ITO transparent electrode cannot be readily used in flexible devices.

Accordingly, there is a need to develop a transparent electrode that can be used in flexible devices. One example is a transparent electrode comprising a carbon nanotube. A transparent electrode comprising a carbon nanotube can be used in a wide range of devices, such as liquid crystal display devices (LCDs), organic light emitting display devices (OLEDs), electronic paper like displays, solar cells and the like.

The transparent electrode comprising a carbon nanotube has conductivity, transparency and flexibility, but these properties still need to be improved.

### BRIEF SUMMARY OF THE INVENTION

Disclosed is a method of improving electrical conductivity of a carbon nanotube, comprising forming a defect on a surface of the carbon nanotube.

Disclosed is a method of improving electrical conductivity of a thin film having a carbon nanotube, forming a defect on a surface of the carbon nanotube contained in the thin film.

The defect is formed through an acid treatment process, or an ultrasonic treatment process, or of both the acid treatment process and the ultrasonic treatment process. The acid treatment process includes immersing the carbon nanotube or the thin film in an acid solution for a predetermined period of time. Here, the acid solution may be stirred. The acid solution includes nitric acid, sulfuric acid, hydrochloric acid, a phosphoric acid, or a mixture thereof.

The ultrasonic treatment process includes immersing the carbon nanotube or the thin film in an aqueous or organic solvent and exposing the solution to an ultrasonic wave having a predetermined frequency and intensity for a predetermined period of time.

Disclosed is a transparent electrode comprising a carbon nanotube, wherein the carbon nanotube has a defect on a surface thereof. The carbon nanotube has an I_{D}/I_{G} ratio of 0.25 or more where I_{D} and I_{G} respectively denote integrated values of the D band and G band of a Raman spectrum of the carbon nanotube.

Disclosed is a method of preparing a transparent electrode comprising a carbon nanotube. The method comprises: dispersing a carbon nanotube powder in a solvent to prepare a carbon nanotube ink; and coating the carbon nanotube ink on a substrate to prepare a carbon nanotube film, wherein the carbon nanotube has a defect formed on a surface thereof.

Further disclosed are various electronic devices using the above carbon nanotube having defects or the transparent electrode formed of the carbon nanotubes.

### BRIEF DESCRIPTION OF THE DRAWINGS

The above and other features and advantages of the disclosed embodiments will become more apparent by describing in detail exemplary embodiments thereof with reference to the attached drawings in which:

FIG. 1 is a graph illustrating Raman spectra for a carbon nanotube before being treated, a carbon nanotube after an acid treatment process while stirring, and a carbon nanotube after an acid treatment process together with an ultrasonic treatment process;

FIG. 2 is a partial enlarged view of FIG. 1;

FIG. 3 is a graph illustrating Raman spectra for a carbon nanotube before being treated, a carbon nanotube after an acid treatment process while stirring, and a carbon nanotube after an acid treatment process together with an ultrasonic treatment process; and

FIG. 4 is an exemplary schematic view of a solar cell according to one embodiment.

### DETAILED DESCRIPTION OF THE INVENTION

Disclosed embodiments will now be described more fully with reference to the accompanying drawings, in which exemplary embodiments are shown.

It will be understood that when an element is referred to as being “on” another element, it can be directly on the other element or intervening elements may be present therebetween. In contrast, when an element is referred to as being “disposed on” or “formed on” another element, the elements are understood to be in at least partial contact with each other, unless otherwise specified.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but are included to identify individual elements. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements and the thicknesses of layer and regions are exaggerated for clarity.

A transparent electrode comprising a carbon nanotube according to an embodiment has a high conductivity and thus provides a wider range of applications.

The transparent electrode comprising a carbon nanotube is prepared by dispersing a carbon nanotube powder in a solution to form a carbon nanotube ink and then coating the carbon nanotube ink on a substrate to form a carbon nanotube film. The transparent electrode, i.e., the carbon nanotube film, has a network structure formed of carbon nanotubes. As a result, electrons flow through the carbon nanotubes themselves and between the carbon nanotubes. Accordingly, its conductivity is determined by the amount of electrons flowing through the carbon nanotubes themselves and between the carbon nanotubes.

In the transparent electrode having the network structure of carbon nanotubes, when the number of the carbon nanotubes is sufficiently large such that the carbon nanotubes can contact each other, that is, when the number of carbon nanotubes is equal to or higher than a percolation threshold, the carbon nanotube network film is not affected by the resistance of the carbon nanotubes themselves, but dominated mainly by the contact resistance between the carbon nanotubes. As a result, the carbon nanotube film has a resistance greater than that of the carbon nanotubes themselves and thus, the carbon nanotube film has a lower conductivity, relative to the carbon nanotubes themselves.

In this embodiment, the conductivity of a carbon nanotube or a carbon nanotube film can be improved by forming defects at the surface of the carbon nanotubes forming a transparent electrode and thus allowing electrons to be emitted easily through the defects.

In general, a carbon nanotube is formed of a sheet of graphite rolled-up into a cylinder form. In the sheet of graphite, carbon atoms are arranged in a hexagonal structure. A carbon nanotube formed of a single sheet is known as a single-walled carbon nanotube (SWNT), a carbon nanotube formed of two to five sheets is known as a thin multi-walled carbon nanotube (t-MWNT), and a carbon nanotube formed of more than five sheets is known as a multi-walled carbon nanotube (MWNT).

In this embodiment, the conductivity of the carbon nanotube is improved by forming defects at the surface of the carbon nanotube. The defects are formed through specific treatment processes on the carbon nanotube, for example, an acid treatment process, an ultrasonic treatment process, or a combination thereof. Through these treatment processes, the carbon nanotube has defects at its surface and electrons can be easily emitted through formed defects. As a result, the resistance of the carbon nanotube film, which has been increased by the contact resistance between the carbon nanotubes, can be decreased to thereby improve the conductivity of the carbon nanotube film.

More specifically, when the acid treatment or ultrasonic wave treatment is performed on applied to CNTs, the carbon-carbon bonds at the surface of CNTs are broken to thereby form various defects, for example, C—OH, C—O—C, or C—OOH. In absence of such defects on the surface of CNTs, the electrons flowing inside a CNT cannot easily come out of the CNT. On the other hand, when the surface of CNTs have such defects, the electrons flowing inside the CNTs can easily come out of the CNTs. That is, in a carbon nanotube network, the electrons can easily flow out of one CNT and enter other neighboring CNTs through contacts in-between. As described above, the resistance of the carbon nanotube network film is dominated mainly by the contact resistance between the carbon nanotubes. Therefore, the entire resistance of the CNT network or the CNT electrode can be significantly reduced.

Defects of the carbon nanotube can be spectroscopically quantified, for example, using integral values of a D band and a G band of a Raman spectrum.

A Raman spectrum is obtained using the Raman spectroscopic technique, which is generally used to identify, verify, and quantify features of molecules. According to the Raman spectroscopic technique, information about a molecular vibration-rotation state can be obtained using inelastically scattered light from a non-resonance or non-ionization radiation source, such as visible light or near-infrared light source, such as a laser. Typically, a Raman spectrum is illustrated as a plot of the intensity (a.u.) with respect to Raman shift. The Raman shift is a difference of energy or wavelength between an excited light and a scattered light, and is generally represented by units of wave number (cm⁻¹), i.e., an inverse number of wavelength shift (cm). The obtained Raman spectrum is not restrictive, but the effective range includes the range of wave numbers of the polyatomic vibration, typically a Raman shift corresponds to about 100 to about 4000 cm⁻¹ (stokes and/or anti-stokes).

In general, the Raman spectrum of a carbon nanotube includes a radial breathing mode band (RBM) at 150 to 350 cm⁻¹, a G band at 1300 to 1400 cm⁻¹, and a D band at 1570 to 1590 cm⁻¹. The RBM band is formed due to radial vibration of the carbon nanotube and the G band is formed due to tangential vibration of the carbon nanotube. The RBM band represents the SP² bond of a graphite structure, and the D band represents the SP³ bond of a diamond structure. In general, the D band increases when the SP² bond of the graphite structure is changed into the SP³ bond. The RBM, D, and G bands have various locations and shapes according to the diameter of a carbon nanotube or the wavelength of a laser used.

In the Raman spectrum of a carbon nanotube, the D band increases when the carbon nanotube has defects, and thus, a degree of formation of defects of the carbon nanotube can be quantified by evaluating a ratio of an integral value of the D band with respect to an integral value of the G band.

In this embodiment, the carbon nanotube has defects at its surface, so that electrons can be easily emitted and its conductivity is improved. Accordingly, in the Raman spectrum, a higher ratio of the integral value of the G band to the integral value of the D band is desired. For example, I_{D}/I_{G} of the carbon nanotube having defects is equal to or greater than 0.25. Here, I_{D} denotes the integral value of the D band and I_{G} denotes the integral value of the G band. When the I_{D}/I_{G} of the carbon nanotube having defects is less than 0.25, less defects are formed and thus conductivity is insufficiently improved. The I_{D}/I_{G} of the carbon nanotube having defects may be in the range of 0.25 to 1.00.

The carbon nanotube forming the transparent electrode can be a single-walled carbon nanotube, a thin multi-walled carbon nanotube, a multi-walled carbon nanotube, or a mixture thereof. However, other types of carbon nanotube can be employed. The carbon nanotube may have an average length of 0.5 to 500 μm based on a bundle of carbon nanotubes. A commercial carbon nanotube can also be used after being subjected to a mechanical treatment process, for example, ball milling at low temperature to obtain short carbon nanotubes. Considering contact resistance, carbon nanotubes having an average length of 0.1 to 500 μm are used.

The carbon nanotubes having defects at their surfaces are used to form a transparent electrode generally in the form of a thin film. The transparent electrode film is prepared by performing an acid treatment process or an ultrasonic treatment process on a carbon nanotube powder and then forming the treated carbon nanotube powder into a film. Alternatively, the transparent electrode film can be formed by forming a carbon nanotube powder into a film and then performing an acid treatment process or an ultrasonic treatment process on the carbon nanotube film. In addition, the transparent electrode film can be formed by performing an acid treatment process or an ultrasonic treatment process on a carbon nanotube powder, forming the treated carbon nanotube powder into a film, and then again performing an acid treatment process or an ultrasonic treatment process on the carbon nanotube film. The acid treatment process or the ultrasonic treatment process can be performed separately or simultaneously to form defects.

This transparent electrode comprising the defective carbon nanotube has flexibility so that the transparent electrode can be used in various flexible devices, such as liquid crystal displays (LCDs), organic light emitting display devices (OLEDs), or solar cells. Display devices having the flexible transparent electrode can be easily bent to provide a greater convenience of use. A solar cell having the flexible transparent electrode can be structured to have curvatures so as to receive light from various directions of light, so that light can be more efficiently used.

When the transparent electrode comprising a carbon nanotube is used in various devices, the thickness of the transparent electrode can be appropriately adjusted, considering required transparency. For example, the transparent electrode may be formed to have a thickness in the range of 5 to 500 nm. When the thickness of the transparent electrode is greater than 500 nm, the transparency may decrease and light efficiency may decrease. On the other hand, when the thickness of the transparent electrode is less than 5 nm, the surface resistance can be very low or the carbon nanotube film can be non-uniform.

Hereafter, a method of preparing the transparent electrode comprising a carbon nanotube will now be described in detail.

First, a carbon nanotube powder is dispersed in a solvent to form a carbon nanotube ink, the carbon nanotube ink is coated on a substrate to obtain a carbon nanotube film, and then the carbon nanotube film is subjected to an acid treatment process, an ultrasonic treatment process, or acid/ultrasonic treatment processes. As a result, a transparent electrode which includes a carbon nanotube having defects at its surface is prepared. Throughout the description, the substrate may be a flexible one such as plastic substrates.

Alternatively, a carbon nanotube powder may be subjected to an acid treatment process, an ultrasonic treatment process, or acid/ultrasonic treatment processes, the treated carbon nanotube powder is dispersed in a solvent to form a carbon nanotube ink, and then the carbon nanotube ink is coated on a substrate to prepare a transparent electrode which includes a carbon nanotube having defects at its surface.

In addition, the carbon nanotube film obtained using the carbon nanotube powder which has been subjected to an acid treatment process and/or an ultrasonic treatment process can be additionally subjected to an acid treatment process or an ultrasonic treatment process.

The acid treatment process is performed by immersing the carbon nanotube powder or the carbon nanotube film in a nitric acid, a sulfuric acid, a hydrochloric acid, or a phosphoric acid for a predetermined period of time. Accordingly, a degree of the defect formation at the surface of the carbon nanotube can be controlled by adjusting the concentration of such acid solutions or the treating time.

The time for which the acid treatment process is performed may vary according to the concentration of an acid solution to be used and the amount of carbon nanotubes to be treated. The acid treatment process can be performed for 1 minute to 100 hours. When the acid treatment process time is outside this range, excessive defects are formed and thus the carbon nanotube may be partly or completely broken, or not sufficient defects are formed.

The acid treatment process may be performed by immersion alone, or, by immersion and stirring to uniformly form defects in the carbon nanotube.

The acid treatment process may be directly performed on the carbon nanotube powder, on the carbon nanotube film obtained using the carbon nanotube powder, or twice both on the carbon nanotube powder and on the carbon nanotube film.

The carbon nanotube having defects can be formed using, in addition to the acid treatment process, an ultrasonic treatment process. In the ultrasonic treatment process, a carbon nanotube film is immersed in an aqueous or organic solvent such as water, ethanol, chloroform, chlorobenzene, dichlorobenzene, or dichloroethane, and then exposed to an appropriate frequency of an ultrasonic wave having an appropriate intensity for a predetermined period of time, thereby forming defects at the surface of the carbon nanotube.

The ultrasonic wave may have a frequency of 10 kHz to 150 kHz, specifically 20 to 130 kHz, and more specifically 30 to 120 kHz at an output power of 100 to 1000 W. The ultrasonic treatment process time may vary with the frequency range of the ultrasonic wave and the amount of carbon nanotubes to be treated. The ultrasonic treatment process can be performed for 1 minute to 100 hours, but not limited thereto.

The ultrasonic treatment process can be performed alone or together with the acid treatment process. When the acid treatment process and the ultrasonic treatment process are performed together, the acid treatment process and the ultrasonic treatment process can be sequentially or simultaneously performed. When the acid treatment process and the ultrasonic treatment process are simultaneously performed, the carbon nanotube powder or film is immersed in an acid solution and then an ultrasonic wave can be directly applied thereto.

As described above, before or after the acid treatment process or the ultrasonic treatment process is performed, a carbon nanotube film is formed using carbon nanotube powder. Specifically, the carbon nanotube film is formed by dispersing a carbon nanotube powder in an aqueous or organic solution, such as water, ethanol, chloroform, chlorobenzene, dichlorobenzene, or dichloroethane to prepare a carbon nanotube ink, coating the carbon nanotube ink on a substrate, such as PP, PE, PET, PS, PES, or PAN, and then drying the coated carbon nanotube to form a carbon nanotube film, which is a transparent electrode.

The transparent electrode comprising carbon nanotubes having defects at their surfaces obtained as described above has high conductivity and excellent flexibility, so that the transparent electrode can be efficiently used in various devices. For example, the transparent electrode can be used as a transparent electrode of a solar cell, or as a transparent electrode of various display devices, such as a liquid display device or an organic light emitting display device.

A solar cell, specifically a dye-sensitized solar cell is illustrated in FIG. 4. Referring to FIG. 4, the dye-sensitized solar cell includes a semiconductor electrode 10, an electrolyte layer 13, and an opposite electrode 14. The semiconductor electrode 10 includes a conductive transparent substrate 11 and a light absorbance layer 12. The conductive transparent substrate 11 is coated with a colloid solution of a carbon nanotube oxide 12a and heated in an electric furnace at high temperature, and then a dye 12b is adsorbed thereto, thereby producing a solar cell. The semiconductor electrode 10 can be a transparent electrode comprising a carbon nanotube having defects.

Among the display devices, an organic light emitting display device is an active type light emitting display device in which, when a current is applied to a fluorescent or phosphoric organic compound thin layer, electrons are combined with holes in the organic layer, thereby emitting light. A conventional organic light emitting display device includes an anode, a hole transport layer, an emission layer, an electron transport layer, and a cathode, which are sequentially formed on a substrate. In order to easily inject electrons and holes, the organic light emitting display device may further include an electron injection layer and a hole injection layer. Since the anode is formed of a transparent material having high conductivity, the transparent electrode comprising a carbon nanotube having defects can be used as the anode.

The transparent electrode comprising a carbon nanotube having defects can be used in other display devices, such as liquid crystal displays (LCDs), electro-chromic displays (ECDs), electrophoresis displays, or electro-wetting displays, which are categorized according to a display material. When these display materials are combined with a flexible substrate, flexible devices can be obtained. These display devices commonly employ a transparent electrode having high conductivity. Accordingly, the transparent electrode comprising a carbon nanotube having defects can be effectively used in these display devices.

The following examples are for illustrative purposes only and are not intended to limit the scope of the present invention.

### EXAMPLE 1

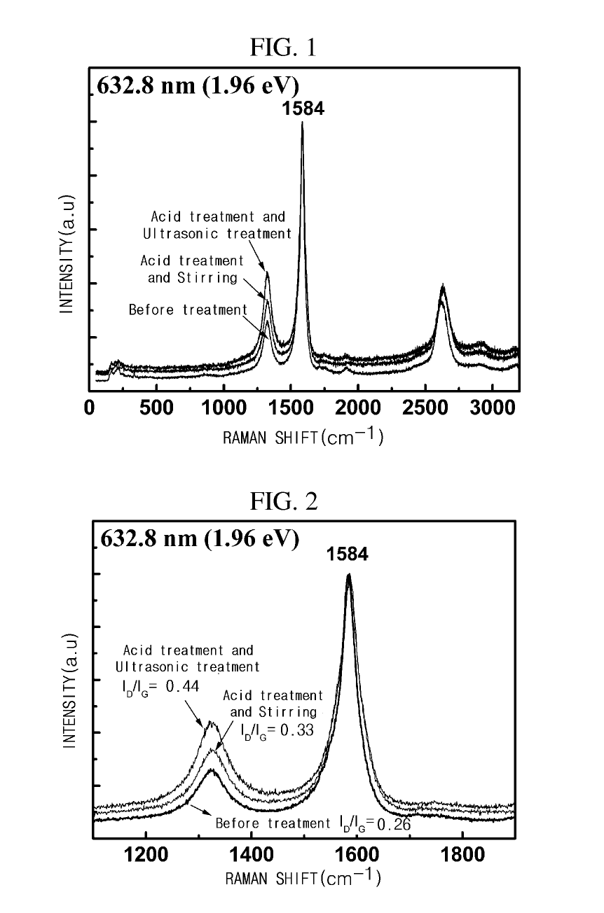

A thin multi-walled carbon nanotube (ILJIN CMP-320F, produced by Iljin Co.) was subjected to an acid treatment process to form defects in the carbon nanotube. The carbon nanotube having defects was then used to form a carbon nanotube electrode, and the surface resistance of the carbon nanotube electrode was measured. In detail, 7 mg of a carbon nanotube was subjected to an acid treatment process using an acid solution (HNO₃ 70%-70 ml). The acid treatment process was performed while stirring or together with an ultrasonic treatment process. When the acid treatment process was performed while stirring, the prepared solution was mixed at 600 rpm for 12 hours. On the other hand, when the acid treatment process was performed together with an ultrasonic treatment process, the acid treatment process was performed using an ultrasonicator (35 kHz, 480 W, RK 106, Bandelin electronic, Berlin, Germany) for 12 hours. After the acid treatment process, a filter (Milipore, PTFE, and pore size: 0.45 μm) was used to obtain a carbon nanotube film, and the obtained film was dried at room temperature for six hours. As a result, a dried carbon nanotube film was obtained. The resistance of the dried film was measured using a 4-probe measurement apparatus (Keithley 2000). Defects of the obtained sample were analyzed using a Raman spectrometer [Renishaw RM1000-Invia with laser excitation energies of 633 nm (1.98 eV) equipped with a notch filter of 50 cm⁻¹ cutoff frequency.] The carbon nanotube subjected to the acid treatment process was measured using Raman spectroscopy. FIGS. 1 and 2 are graphs illustrating Raman spectra for the carbon nanotube before being treated, the carbon nanotube after the acid treatment process while stirring, and the carbon nanotube after the acid treatment process with the ultrasonic treatment process, respectively. A ratio of the integral value of the G band to the integral value of the D band was obtained.

As a result, it was found that, when the acid treatment process was performed while stirring, the carbon nanotube had more defects than the source carbon nanotube, and when the acid treatment process was performed with the ultrasonic treatment process, the carbon nanotube had more defects than when the acid treatment process was performed while stirring. I_{D}/I_{G} values of the source carbon nanotube, the carbon nanotube after the acid treatment process while stirring, and the carbon nanotube after the acid treatment process together with the ultrasonic treatment process were 0.26, 0.33, and 0.44, respectively. At the same time, surface resistances of the source carbon nanotube, the carbon nanotube after the acid treatment process while stirring, and the carbon nanotube after the acid treatment process together with the ultrasonic treatment process were 117.75, 103.26, and 76 Ω/sq (based on 7 mg of carbon nanotube), respectively. These values indicate an improvement of conductivity.

### EXAMPLE 2

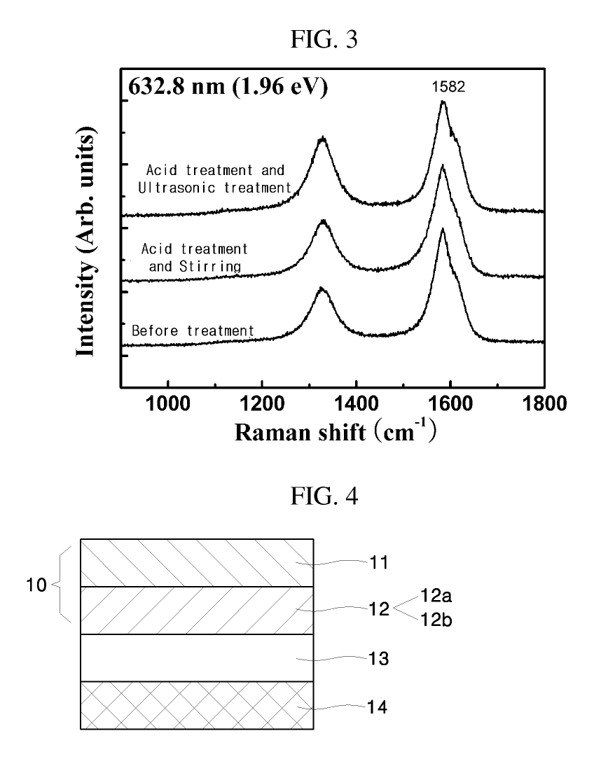

A thin multi-walled carbon nanotube (ILJIN M2, produced by Iljin Co.) was subjected to an acid treatment process to form defects in the carbon nanotube. The carbon nanotube having defects was then used to form a carbon nanotube electrode, and the surface resistance of the carbon nanotube electrode was measured. In detail, 7 mg of a carbon nanotube was subjected to an acid treatment process using an acid solution (HNO₃ 70%-70 ml). The acid treatment process was performed while stirring or together with an ultrasonic treatment process. When the acid treatment process was performed while stirring, the prepared solution was mixed at 600 rpm for 12 hours. On the other hand, when the acid treatment process was performed together with an ultrasonic treatment process, the acid treatment process was performed using an ultrasonicator (35 kHz, 480 W, RK 106, Bandelin electronic, Berlin, Germany) for 12 hours. After the acid treatment process, a filter (Milipore, PTFE, and pore size: 0.45 μm) was used to obtain a carbon nanotube film, and the obtained film was dried at room temperature for six hours. As a result, a dried carbon nanotube film was obtained. The resistance of the dried film was measured using a 4-probe measurement equipment (Keithley 2000). Defects of the obtained sample were analyzed using a Raman spectrometer [Renishaw RM1000-Invia with laser excitation energies of 633 nm (1.98 eV) equipped with a notch filter of 50 cm⁻¹ cutoff frequency.] The carbon nanotube subjected to the acid treatment process was measured using Raman spectroscopy. FIG. 3 is a graph illustrating Raman spectra for the carbon nanotube before being treated, the carbon nanotube after the acid treatment process while stirring, and the carbon nanotube after the acid treatment process together with the ultrasonic treatment process. A ratio of the integral value of the G band to the integral value of the D band was obtained.

As a result, it was found that the carbon nanotube after the acid treatment process while stirring had more defects than the source carbon nanotube, and the carbon nanotube after the acid treatment process with the ultrasonic treatment process had more defects than the carbon nanotube after the acid treatment process while stirring. I_{D}/I_{G} values of the source carbon nanotube, the carbon nanotube after the acid treatment process while stirring, and the carbon nanotube after the acid treatment process with the ultrasonic treatment process were 0.53, 0.56, and 0.72, respectively. At the same time, surface resistances of the source carbon nanotube, the carbon nanotube after the acid treatment process while stirring, and the carbon nanotube after the acid treatment process with the ultrasonic treatment process were 64.6, 61.1, and 52.3 Ω/sq (based on 7 mg of carbon nanotube), respectively. These values indicate an improvement of conductivity.

### EXAMPLE 3

A thin multi-walled carbon nanotube (ILJIN CMP-320F, produced by Iljin Co.) was subjected to an acid treatment process to form defects in the carbon nanotube. The carbon nanotube having defects was then used to form a carbon nanotube electrode, and the surface resistance of the carbon nanotube electrode was measured. In detail, 7 mg of a carbon nanotube was subjected to an acid treatment process using an acid solution (HNO₃ 70%-70 ml). The current example was performed to determine a change in defects and conductivity with respect to an ultrasonic treatment process time when the ultrasonic treatment process is performed. The acid treatment process was performed together with an ultrasonic treatment process using an ultrasonicator (35 kHz, 480 W, RK 106, Bandelin electronic, Berlin, Germany) for 6, 12, and 24 hours. After the acid treatment process, a filter (Milipore—PTFE, Pore size of 0.45 μm) was used to obtain a carbon nanotube film, and the obtained film was dried at room temperature for six hours. As a result, a dried carbon nanotube film was obtained. The resistance of the prepared film was measured using a 4-probe measurement equipment (Keithley 2000). Defects in the obtained sample were analyzed by measuring the surface resistance using a Raman spectrometer (Renishaw RM1000-Invia with laser excitation energies of 633 nm (1.98 eV) equipped with a notch filter of 50 cm⁻¹ cutoff frequency.). After the carbon nanotube subjected to the acid treatment process was measured using Raman spectroscopy, a ratio of the integral value of the G band to the integral value of the D band was calculated. As the source carbon nanotube was treated for 6 hours, 12 hours, and 24 hours, the amount of defects (I_{D}/I_{G}) was increased to 0.26, 0.34, 0.42, and 0.56 and the surface resistance (based on 7 mg of the carbon nanotube) was decreased to 189.3, 157.65, 144.81, and 79.29 Ω/sq. Therefore, it was found that the conductivity of the carbon nanotube was improved by means of the ultrasonic treatment process.

As described above, the conductivity of a transparent electrode comprising carbon nanotube networks is improved by forming defects in the carbon nanotube.

While disclosed embodiments have been shown and described with reference to exemplary embodiments thereof, it will be understood by those of ordinary skill in the art that various changes in form and details may be made therein without departing from the spirit and scope of the present invention as defined by the following claims.

In addition, many modifications can be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims. Moreover, the use of the terms first, second, etc. do not denote any order or importance, but rather the terms first, second, etc. are used to distinguished one element from another. Furthermore, the use of the terms a, an, etc. do not denote a limitation of quantity, but rather denote the presence of at least one of the referenced item.

What is claimed is:

1. A method of improving electrical conductivity of a carbon nanotube, comprising forming a defect on a surface of the carbon nanotube.

2. The method of claim 1, wherein the defect is formed through an acid treatment process, or an ultrasonic treatment process, or both by the acid treatment process and the ultrasonic treatment process.

3. The method of claim 2, wherein the acid treatment process includes immersing the carbon nanotube in an acid solution for a predetermined period of time.

4. The method of claim 3, wherein the acid solution is stirred.

5. The method of claim 3, wherein the acid solution is nitric acid, sulfuric acid, hydrochloric acid, or a phosphoric acid.

6. The method of claim 2, wherein the ultrasonic treatment process includes immersing a carbon nanotube in an aqueous or organic solvent to form a carbon nanotube solution and exposing the carbon nanotube solution to an ultrasonic wave having a predetermined frequency and intensity for a predetermined period of time.

7. A method of improving electrical conductivity of a thin film having a carbon nanotube comprising, forming a defect on a surface of the carbon nanotube contained in the thin film.

8. The method of claim 7, wherein the defect is formed through an acid treatment process, or an ultrasonic treatment process, or both of the acid treatment process and the ultrasonic treatment process.

9. The method of claim 8, wherein the acid treatment process includes immersing the thin film in an acid solution for a predetermined period of time.

10. The method of claim 9, wherein the acid solution is stirred.

11. The method of claim 9, wherein the acid solution is nitric acid, sulfuric acid, hydrochloric acid, a phosphoric acid, or a mixture thereof.

12. The method of claim 8, wherein the ultrasonic treatment process includes immersing the thin film in an aqueous or organic solvent and exposing the solution to an ultrasonic wave having a predetermined frequency and intensity for a predetermined period of time.

13. A transparent electrode comprising a carbon nanotube, wherein the carbon nanotube has a defect on a surface thereof.

14. The transparent electrode of claim 13, wherein the carbon nanotube has an I_{D}/I_{G} ratio of 0.25 or more where I_{D} and I_{G} respectively denote integrated values of the D band and G band of a Raman spectrum of the carbon nanotube.

15. The transparent electrode of claim 14, wherein the I_{D}/I_{G} ratio of the carbon nanotube is in a range of 0.25 to 1.00.

16. The transparent electrode of claim 13, wherein the defect is formed through an acid treatment process, or an ultrasonic treatment process, or both of the acid treatment process and the ultrasonic treatment process.

17. The transparent electrode of claim 13, wherein the transparent electrode has a thickness of 5 nm to 500 nm.

18. A method of preparing a transparent electrode comprising a carbon nanotube, the method comprising:
dispersing a carbon nanotube powder in a solvent to prepare a carbon nanotube ink; and
coating the carbon nanotube ink on a substrate to prepare a carbon nanotube film,
wherein the carbon nanotube has a defect formed on a surface thereof.

19. The method of claim 18, wherein the defect is formed through an acid treatment process, an ultrasonic treatment process, or both the acid treatment process and the ultrasonic treatment process.

20. The method of claim 19, wherein the acid treatment process comprises immersing the carbon nanotube powder or the carbon nanotube film in nitric acid, sulfuric acid, hydrochloric acid, phosphoric acid, or a mixture thereof.

21. The method of claim 20, wherein the acid is stirred.

22. The method of claim 19, wherein the ultrasonic treatment process is performed by exposing the carbon nanotube powder or the carbon nanotube film to an ultrasonic wave having a predetermined frequency and intensity.

23. The method of claim 19, wherein the carbon nanotube formed with the defect has an I_{D}/I_{G} ratio of 0.25 or more where I_{D} and I_{G} respectively denote integrated values of a D band and G band of a Raman spectrum of the carbon nanotube.

24. A display device comprising the transparent electrode claimed in claim 13.

25. A solar cell comprising the transparent electrode claimed in claim 13.
